(19) United States
(12) Patent Application Publication
(10) Pub. No.: US 2005/0006770 A1
(43) Pub. Date: Jan. 13, 2005

(54) Copper-low-K dual damascene interconnect with improved reliability

(76) Inventors: Valeriy Sukharev, Cupertino, CA (US); Ratan Choudhury, Milpitas, CA (US); Chong Park, Cupertino, CA (US)

Correspondence Address: LSI LOGIC CORPORATION, 1621 BARBER LANE, MS: D-106, MILPITAS, CA, 95035, US

(21) Appl. No.: 10/615,042

(22) Filed: Jul. 8, 2003

(51) Int. Cl. H01L 23/48; H01L 21/4763

(52) U.S. Cl. 257/758; 438/622

(57) ABSTRACT

A dual damascene-based interconnect structure which includes a liner of aluminum-0.5% copper alloy. The alloy can be implemented by depositing the alloy using a conventional PVD technique. To completely secure against copper atoms possibly penetrating through the aluminum-0.5% copper alloy, one or more Ta/TaN liners can be employed in addition to the aluminum-0.5% copper alloy liner. If Ta/taN is to be used, preferably the Ta/TaN is deposited before the aluminum-0.5% copper alloy is deposited.

### BACKGROUND

The present invention generally relates to CMOS interconnect structures, and more specifically relates to an interconnect liner for a CMOS interconnect structure.

Since the introduction of 0.25 μm technology, interconnects are becoming the limiting factor for device speed, primarily due to interconnect resistivity as well as the RC delay induced by adjacent interconnects. A solution for reducing the resistance of an interconnect is to use copper rather than aluminum. Copper has been chosen because it is a metal with better conductivity than aluminum, and it has good resistance to electromigration (EM).

Since copper cannot be easily dry etched, the use of damascene or dual damascene structures is becoming a key solution to realize copper integration. In a damascene-type structure, the pattern is etched into a dielectric layer, followed by metal fill and planarization. Dual damascene structures are advantageous in that they incorporate both lines and vias in one deposition step. This reduces the number of process steps and, as a result, is cost-effective. More specifically, two patterning steps are used to create features of two different depths, blanket metal is deposited, and then a single chemical mechanical polishing (CMP) step is used to create the inlaid structure. This is the current process used by many integrated circuit (IC) companies to integrate copper into a circuit.

Implementation of copper and low-K materials as major components of interconnect structures has resulted in some new electromigration (EM)-induced problems that have not been detected in the case of aluminum interconnects. This is especially true for copper metallization characterized by the complicated geometry of dual damascene interconnect segments, and by much lower critical stress for void nucleation than aluminum. The latter fact clarifies an important role of non-uniform stress, current distribution and temperature distribution in failure development. Another important aspect is the presence of a “weak” interface between copper and an etch stop layer such as silicon nitride (SiN) or silicon carbide (SiC). This interface is characterized by fast migration of the copper atoms in comparison with other migration channels, such as grain bulks, grain boundaries and interfaces between copper and diffusion bather liners, for example, Ta/TaN. Experimental studies demonstrate that such copper dual damascene segments result in bimodal failure. As such, some structures fail early, which results in a very short mean-time-to-failure (MTF), which is a factor of 100-1000 shorter than a typical MTF. A lot of effort has been spent to increase a copper-based interconnect's resistance to EM-induced failure. A main direction has been incorporation of an additional process step, which is the deposition of cobalt-tungsten alloy capping. This additional layer removes the copper-SiN(SiC) interface, which is responsible for the reduced MTF of the copper interconnect.

This approach can improve the overall interconnect resistance to EM-induced failure. However, it cannot affect early failure, which is perhaps the most dangerous type of failure in that it renders the chip unuseable. On the basis of available experimental data, it can be concluded that one of the characteristics which contributes to early failure is a void formed at the bottom of a via. If nucleation of such type of voids can be suppressed, then early failure can be eliminated. Of course, this would not mean that the interconnect will be completely EM-failure resistant, as any of the via-containing segments can fail. However, the failure will take longer to occur, and will be caused by a void nucleated at the top corner of the upper line and extended along the line.

In the past, a transient, three-dimensional, fully-linked EM-model has been developed. The developed model targets void nucleation and its growth kinetics as a function of the segment geometry, interconnect architecture and the electrical loading. Coupling of the electromagnetics, heat transfer, structural mechanics and atom migration models, based on a direct solution of the system of partial differential equations in the finite element method (FEM) environment, has allowed for the simulation of stress-induced void nucleation and growth in different interconnect segments. Implementation of this model into a simulation scheme illustrates that there is void nucleation in the case of dual damascene via segment, and that the void leads to long-term failure in the case of highly-conductive liners. Simulation results demonstrate that the character of void evolution strongly depends on the liner conductivity. If this conductivity is very low, then the void nucleates quickly at the bottom of the via. The lower the liner conductivity, the faster void nucleation occurs. Simulations with regard to almost nonconductive liners show that the void at the bottom of the via results in early failure. It should be noted that the nucleation time for the latter void is shorter, by a factor of 100-1000, than for the previous one.

Hence, to be able to suppress void nucleation at the bottom of a via, thereby eliminating the cause of early failure, the conductivity of the via liner must be increased. Liners in the case of copper interconnect are intended to protect the inter-layer dielectric (ILD) from copper diffusion. Typically, refractory metals are used as an interconnect liner and there is a reason. Refractory materials such as Ti/TiN or Ta/TaN are characterized by an extremely low intrinsic diffusivity as well as diffusivity of impurities, which is important property for a diffusion barrier. However, at the same time, these materials are characterized by a low electrical conductivity, which might be responsible for void nucleation at the bottom of a via.

### OBJECTS AND SUMMARY

An object of an embodiment of the present invention is to provide a copper dual damascene-based interconnect which is characterized by an enhanced resistance to early failure.

Another object of an embodiment of the present invention is to provide a copper dual damascene-based interconnect which is characterized by a low intrinsic diffusivity, a low diffusivity of impurities, and high electrical conductivity.

Still another object of an embodiment of the present invention is to provide a copper dual damascene-based interconnect liner which adheres well to both copper and silicon oxide.

Still yet another object of an embodiment of the present invention is to provide a copper dual damascene-based interconnect liner which eliminates early failure, increases interconnect MTF, and improves overall interconnect reliability.

Briefly, and in accordance with at least one of the foregoing objects, an embodiment of the present invention provides a dual damascene-based interconnect structure which includes a liner of aluminum-0.5% copper alloy. The alloy can be implemented by depositing the alloy using a conventional PVD technique. To completely secure against copper atoms possibly penetrating through the aluminum-0.5% copper alloy, one or more Ta/TaN liners can be employed in addition to the aluminum-0.5% copper alloy liner. If Ta/taN is to be used, preferably the Ta/TaN is deposited before the aluminum-0.5% copper alloy is deposited.

### BRIEF DESCRIPTION OF THE DRAWINGS

The organization and manner of the structure and operation of the invention, together with further objects and advantages thereof, may best be understood by reference to the following description, taken in connection with the accompanying drawing, wherein:

FIG. 1 provides a block diagram which illustrates a method of forming an interconnect in accordance with an embodiment of the present invention;

FIGS. 2-5 provide enlarged, cross-sectional views which illustrate the different steps of forming the interconnect, with FIG. 5 illustrating the interconnect after it has been formed; and

FIG. 6 provides a block diagram which illustrates a method of forming an interconnect in accordance with another embodiment of the present invention;

FIGS. 7-9 are enlarged, cross-sectional views which relate to the forming of an interconnect similar to that which is shown in FIG. 5, but where the interconnect includes an additional liner, preferably formed of Ta/TaN.

### DESCRIPTION

While the invention may be susceptible to embodiment in different forms, there are shown in the drawings, and herein will be described in detail, specific embodiments with the understanding that the present disclosure is to be considered an exemplification of the principles of the invention, and is not intended to limit the invention to that as illustrated and described herein.

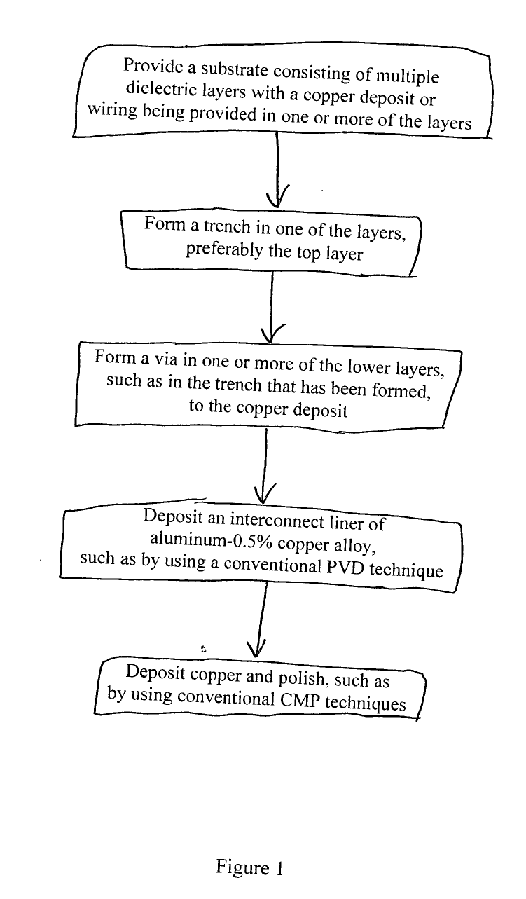

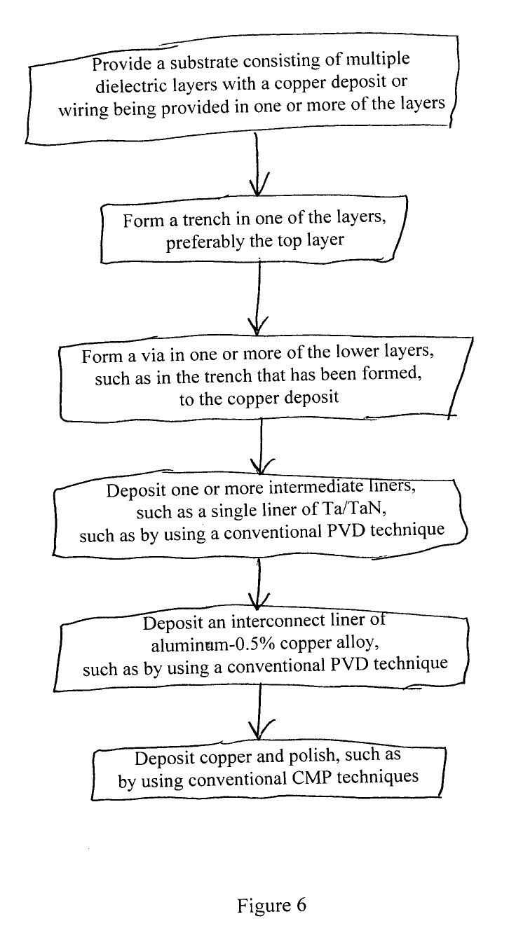

FIGS. 1 and 6 illustrate methods of forming an interconnect, where the methods are in accordance with embodiments of the present invention, while the remaining Figures show the interconnect as it is being formed. Specifically, the interconnect is a copper dual damascene-based interconnect which is characterized by an enhanced resistance to early failure, a low intrinsic diffusivity, a low diffusivity of impurities, high electrical conductivity, and by adhering well to both copper and silicon oxide. The interconnect eliminates early failure, increases interconnect MTF, and improves overall interconnect reliability.

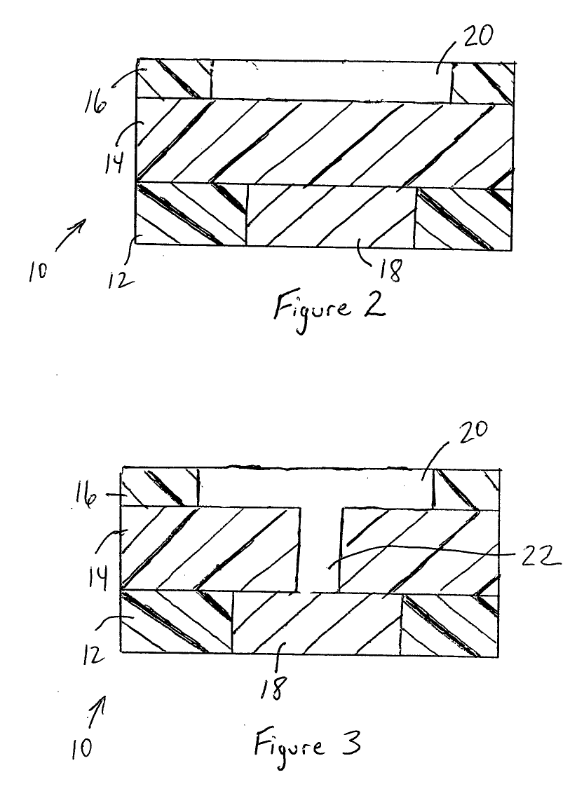

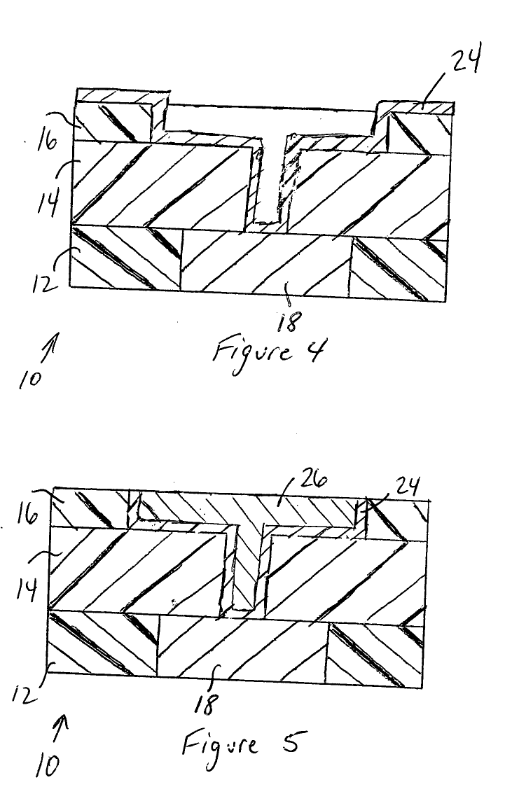

FIG. 1 provides a block diagram which illustrates a method of forming an interconnect in accordance with an embodiment of the present invention. FIGS. 2-5 illustrate the different steps of forming the interconnect, with FIG. 5 illustrating the interconnect after it has been formed. As shown in FIGS. 1 and 2, a substrate 10 formed of multiple dielectric layers 12, 14, 16 is provided with a copper deposit or wiring 18 being provided in one of the layers 12, and a trench 20 is formed in one of the layers, preferably the top layer 16. Then, as shown in FIGS. 1 and 3, a via 22 is formed in one or more of the layers 14, such as in the trench 20 that has been formed, to the copper deposit or wiring 18. Then, as shown in FIGS. 1 and 4, an interconnect liner of aluminum-0.5% copper alloy 24 is deposited such as by using a conventional PVD technique. Then, as shown in FIG. 1, copper 26 is deposited and polished, such as by using conventional CMP techniques, so that the interconnect looks as shown in FIG. 5.

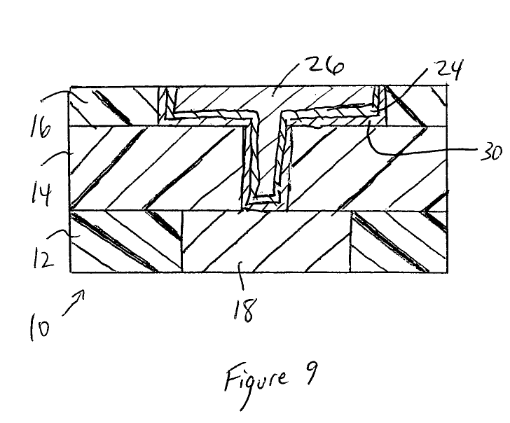

FIG. 6 provides a block diagram which illustrates a method of forming an interconnect in accordance with another embodiment of the present invention. In this embodiment, to be completely secured of the possible copper atoms penetration through the aluminum-0.5% copper alloy-based diffusion barrier into the ILD, one or more Ta/TaN liners is used in addition to aluminum-0.5% copper alloy liner. FIGS. 2, 3 and 7-9 illustrate the different steps of forming the interconnect, with FIG. 9 illustrating the interconnect after it has been formed.

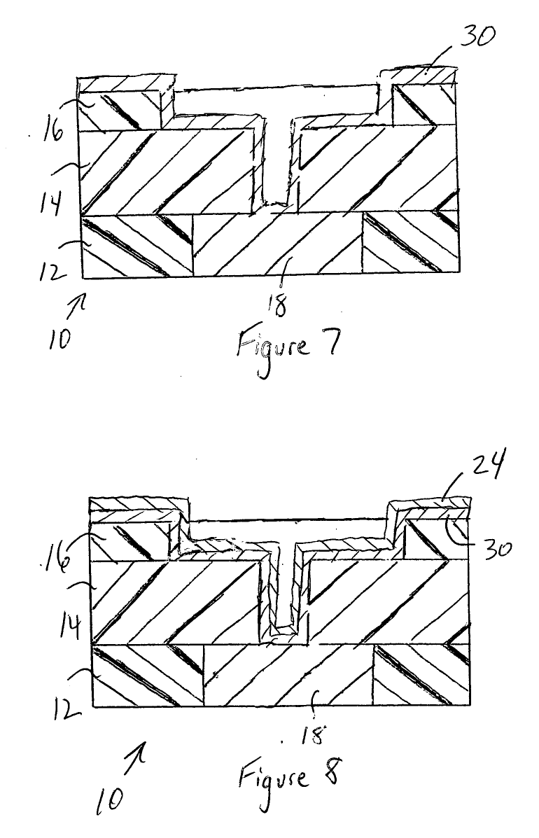

As shown in FIGS. 2 and 6, a substrate 10 formed of multiple dielectric layers 12, 14, 16 are provided with a copper deposit or wiring 18 being provided in one of the layers 12, and a trench 20 is formed in one of the layers, preferably the top layer 16. Then, as shown in FIGS. 3 and 6, a via 22 is formed in one or more of the layers 14, such as in the trench 20 that has been formed, to the copper deposit or wiring 18. Then, as shown in FIGS. 6 and 7, one or more intermediate liners are deposited, such as a single liner of Ta/TaN 30. Then, as shown in FIGS. 6 and 8, a liner of aluminum-0.5% copper alloy 24 is deposited such as by using a conventional PVD technique. Then, as shown in FIG. 6, copper 26 is deposited and polished, such as by using conventional CMP techniques, so that the interconnect looks as shown in FIG. 9.

The aluminum-0.5% copper alloy has a conductivity which is much higher than the conductivity of conventional liners. Additionally, the low diffusivity of copper as well as aluminum atoms is reached by copper atom precipitations at the aluminum grain boundaries. Good adhesion of aluminum to the copper and to silicon oxide, as well as to any oxygen containing compounds, provides additional benefits. Implementing aluminum-0.5% copper alloy, such as by depositing by a conventional PVD technique, as a liner for copper-based interconnect eliminates early failure and improves overall interconnect reliability. To be completely secured of the possible copper atoms penetration through the aluminum-0.5% copper alloy-based diffusion barrier into the ILD, one or more Ta/TaN liners is used in addition to aluminum-0.5% copper alloy liner.

While increasing the thickness of the Ta/TaN layer is a possible way to increase liner conductivity (without employing the aluminum-0.5% copper alloy liner), this will either cause a via width increase, which results in an increase in die size (which is not allowed), or a reduction in the inside-via copper cross-section, which results in total resistivity increase negatively effecting chip performance.

While embodiments of the present invention are shown and described, it is envisioned that those skilled in the art may devise various modifications of the present invention without departing from the spirit and scope of the appended claims.

1. A method of forming an interconnect in a substrate which includes one or more dielectric layers and a copper deposit, said method comprising: forming a trench in the substrate; forming a via in the substrate to the copper deposit; depositing an interconnect liner layer of aluminum-copper alloy comprised primarily of Aluminum in the trench and via; depositing copper onto the aluminum-copper alloy interconnect liner layer; and polishing the copper.

2. A method as recited in claim 1, wherein the step of depositing a layer of aluminum-copper alloy comprises depositing aluminum-0.5% copper alloy using a PVD technique.

3. A method of forming an interconnect in a substrate which includes one or more dielectric layers and a copper deposit, said method comprising: forming a trench in the substrate; forming a via in the substrate to the copper deposit; depositing an intermediate liner layer in the trench and via and on the copper deposit; depositing an interconnect liner layer of aluminum-copper alloy comprised primarily or Aluminum on the intermediate layer; depositing copper onto the aluminum-copper alloy; and polishing the copper.

4. A method as recited in claim 3, wherein the step of depositing a layer of aluminum-copper alloy comprises depositing aluminum-0.5% copper alloy using a PVD technique.

5. A method as recited in claim 3, wherein the step of depositing an intermediate liner layer comprises depositing Ta/TaN.

6. An interconnect in a substrate which includes one or more dielectric layers, said interconnect comprising a first copper deposit, a second copper deposit, and an aluminum-copper alloy interconnect liner comprised primarily of Aluminum and disposed between and in contact with the first and second copper deposits and between the second copper deposit and at least one of the dielectric layers.

7. An interconnect as recited in claim 6, wherein the aluminum-copper alloy interconnect liner has been deposited using a PVD technique.

8. An interconnect in a substrate which includes one or more dielectric layers, said interconnect comprising a first copper deposit, a second copper deposit, an intermediate interconnect liner comprised primarily of Aluminium and disposed between the first and second copper deposits and in contact with the first copper deposit; and an aluminum-copper alloy interconnect liner disposed between the first and second copper deposits between the second copper deposit and at least one of the dielectric layers, and in contact with the second copper deposit.

9. An interconnect as recited in claim 8, wherein the aluminum-copper alloy interconnect liner has been deposited using a PVD technique.

10. An interconnect as recited in claim 8, wherein the intermediate interconnect liner comprises Ta/TaN.

11. A method as recited in claim 1, further comprising depositing the interconnect liner layer such that said interconnect liner is in contact with the copper deposit.

12. A method as recited in claim 1, wherein the step of depositing the interconnect liner layer comprises depositing a layer of aluminum-0.5% copper alloy.

13. A method as recited in claim 3, wherein the step of depositing the interconnect liner layer comprises depositing a layer of aluminum-0.5% copper alloy.

14. An interconnect as recited in claim 8, wherein said aluminum-copper alloy interconnect liner comprises a layer of aluminum-0.5% copper alloy.
